(19) United States
(12) Patent Application Publication
(10) Pub. No.: US 2011/0309394 A1
(43) Pub. Date: Dec. 22, 2011

(54) LED AND METHOD OF MANUFACTURING THE SAME

(75) Inventor: CHIH-CHEN LAI, Tu-Cheng (TW)

(73) Assignee: HON HAI PRECISION INDUSTRY CO., LTD., Tu-Cheng (TW)

(21) Appl. No.: 12/849,823

(22) Filed: Aug. 4, 2010

(30) Foreign Application Priority Data
Jun. 18, 2010 (TW) 99119779

(51) Int. Cl. H01L 33/42; H01L 33/40

(52) U.S. Cl. 257/98; 438/29; 257/E33.064; 257/E33.063

(57) ABSTRACT

An exemplary LED includes an epitaxial layer, an electrically conductive base, a transparent, electrically-conducting layer and a metallic pad. The epitaxial layer includes an N-type layer, a P-type layer and a light-emitting quantum-well layer between the N-type layer and P-type layer. The electrically conductive base is coupled to the P-type layer. The transparent, electrically-conducting layer is coupled to the N-type layer. The metallic pad is disposed on the transparent, electrically-conducting layer.

### BACKGROUND

1. Technical Field

The present disclosure relates to a light emitting diode (LED), and particularly to a method for manufacturing the LED.

2. Description of Related Art

LEDs are used as indicator lamps in many devices, and are increasingly used for lighting due to their high brightness, long lifespan, and wide color range.

Generally, an LED includes a P-type layer, an N-type layer, and a light-emitting layer between the P-type layer and the N-type layer. During operation of the LED, electrons diffuse from the N-type layer to the P-type layer and thus leave positively charged ions (donors) in the N-type layer, and holes diffuse from the P-type layer to the N-type layer and thus leave fixed ions (acceptors) in the P-type layer with negative charge. When an electron meets a hole, it falls into a lower energy level, and releases energy in the form of a photon. However, the electrons tend to move from the N-type layer to the P-type layer along a path with the lowest resistance, and thus usually crowd. A portion of the LED at which the electrons crowd generates a large amount of heat, significantly influencing a lifespan of the LED.

What is needed, therefore, is an LED and a method for manufacturing such LED which can overcome the limitations described.

### BRIEF DESCRIPTION OF THE DRAWINGS

FIG. 1 is a schematic view of an LED in accordance with an embodiment of the disclosure.

FIG. 2 is a flow chart showing a method for manufacturing the LED in accordance with the embodiment of the disclosure of FIG. 1.

FIG. 3 is a schematic view of an LED wafer provided for manufacturing the LED, the LED wafer comprising a substrate and an epitaxial layer.

FIG. 4 shows an electrically conductive base being coupled to the epitaxial layer.

FIG. 5 is a schematic view showing the substrate of the LED wafer being removed to expose the epitaxial layer.

FIG. 6 is a top plan view showing a plurality of grooves being etched in the epitaxial layer.

FIG. 7 is a schematic view showing an electrically insulating material being filled in the grooves of the epitaxial layer.

FIG. 8 shows a conducting layer being formed on the epitaxial layer.

### DETAILED DESCRIPTION

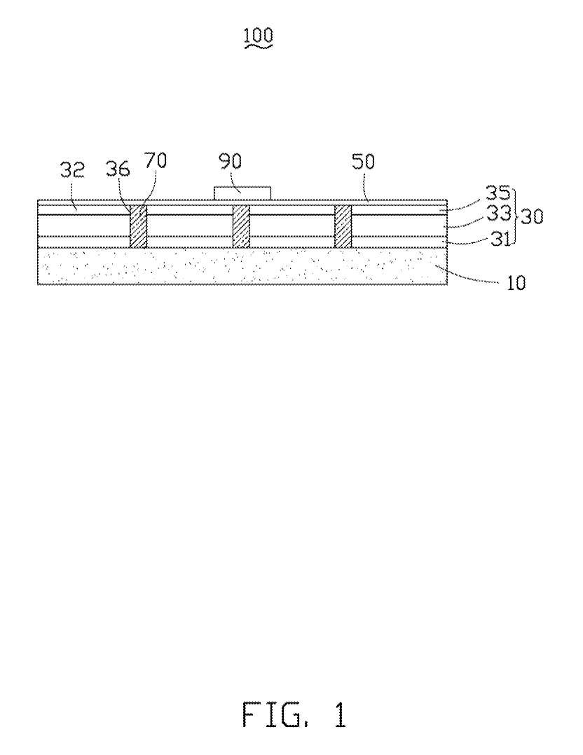

Referring to FIG. 1, an LED 100 in accordance with an exemplary embodiment of the disclosure is shown. The LED 100 includes an electrically conductive base 10, an epitaxial layer 30 on the electrically conductive base 10, a transparent, electrically-conducting layer 50 on the epitaxial layer 30, and a pad 90 on the transparent, electrically-conducting layer 50.

In this embodiment, the electrically conductive base 10 is rectangular and flat. The epitaxial layer 30 is fixed on the electrically conducting layer 50. The epitaxial layer 30 includes a P-type layer 31, a light-emitting quantum-well layer 33, and an N-type layer 35 arranged on the electrically conductive base 10 sequentially. That is, the P-type layer 31 is connected to the electrically conductive base 10, while the N-type layer 35 is away from the electrically conductive base 10.

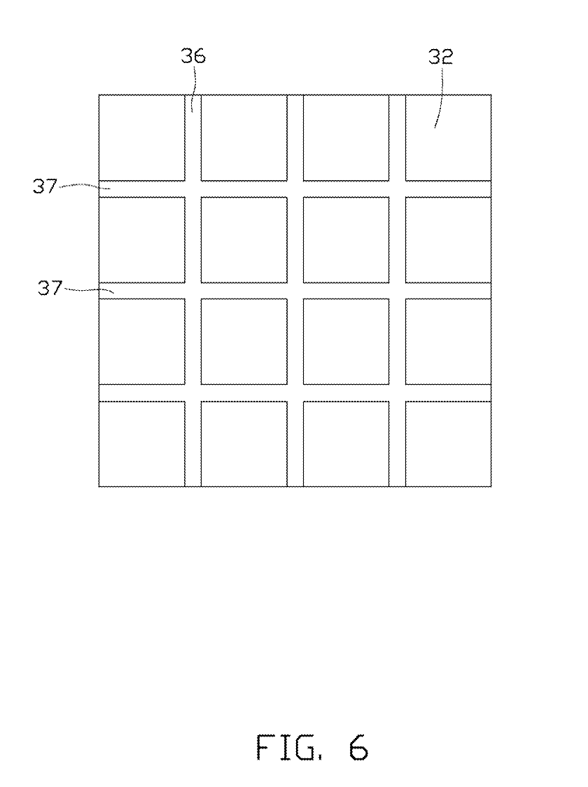

Referring to FIG. 6, a plurality of longitudinal grooves 36 and a plurality of horizontal grooves 37 are defined in the epitaxial layer 30. The longitudinal grooves 36 are parallel to and spaced from each other, and the horizontal grooves 37 are parallel to and spaced from each other. Each horizontal groove 37 intersects the longitudinal grooves 36 perpendicularly. The horizontal grooves 37 and the longitudinal grooves 36 extend through the epitaxial layer 30 along a thickness direction of the epitaxial layer 30, thereby dividing the epitaxial layer 30 into a plurality of separated LED dies 32 which are arranged in multiple rows and multiple columns, as a matrix.

Referring back to FIG. 1, the horizontal grooves 37 and the longitudinal grooves 36 are filled with electrically insulating material 70, such as silicon oxide. Preferably, the electrically insulating material 70 is transparent. Neighboring LED dies 32 are insulated from each other by the electrically insulating material 70. A top of the insulating material 70 is coplanar with a top side of the N-type layer 35 of the epitaxial layer 30. The transparent, electrically-conducting layer 50 covers tops of the N-type layer 35 and the electrically insulating material 70 entirely.

The pad 90 is fixed on the transparent, electrically-conducting layer 50, and is located at a central portion of the transparent, electrically-conducting layer 50. The pad 90 is made of metallic, and is electrically conductive. The pad 90 and the electrically conductive base 10 are at opposite sides of the epitaxial layer 30, and are electrically connected to the N-type layer 35 and the P-type layer 31, respectively. Thus, electric current can be supplied to the epitaxial layer 30 of the LED 100 by connecting the electrically conductive base 10 and the pad 90 to the positive and negative poles of a power source, respectively.

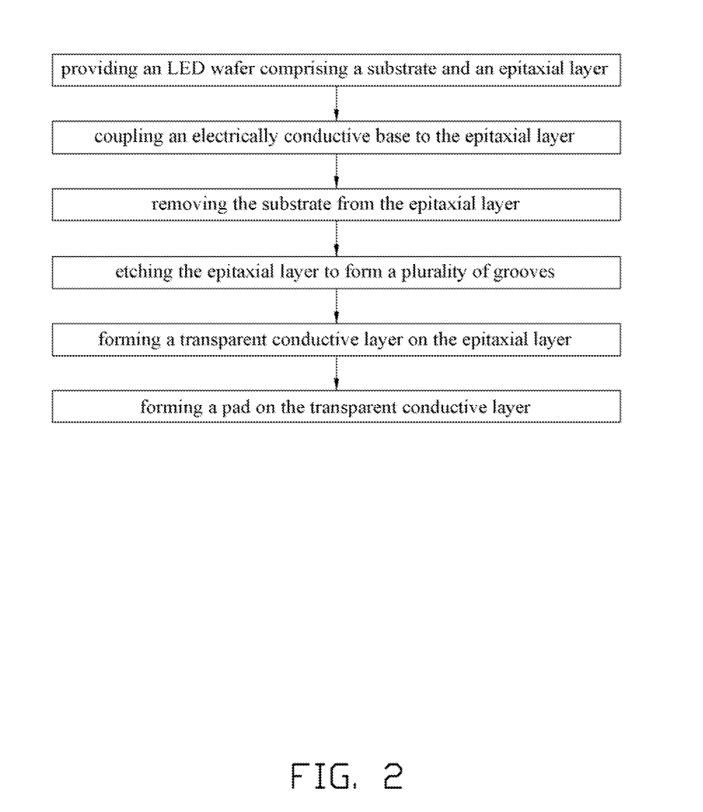

Referring to FIG. 2, a flow chart of a method for manufacturing the LED 100 in accordance with the embodiment is shown. The method mainly includes steps of: providing an LED wafer comprising a substrate and an epitaxial layer; coupling an electrically conductive base to the epitaxial layer; removing the substrate from the epitaxial layer; etching the epitaxial layer to form a plurality of grooves; forming a transparent conducting layer on the epitaxial layer; and forming a pad on the transparent conducting layer, all of which will be disclosed in detail herebelow.

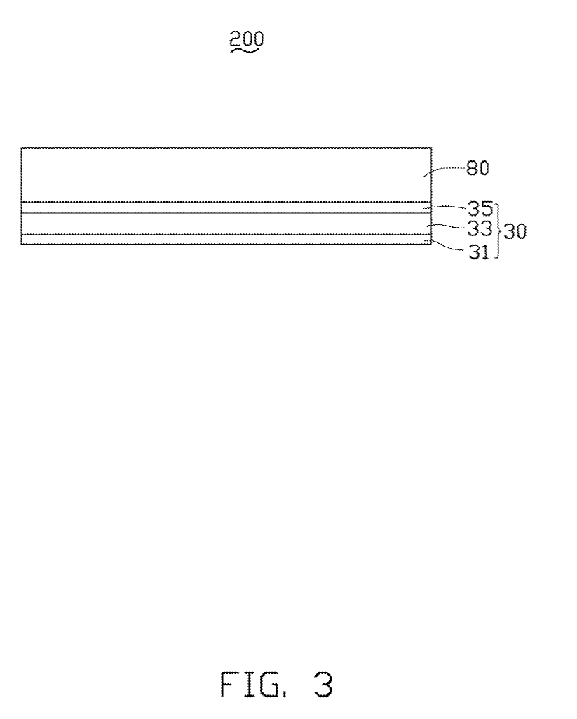

Referring to FIG. 3, firstly, an LED wafer 200 is provided. The LED wafer 200 is formed by growing an epitaxial layer 30 on a substrate 80. The substrate 80 is sapphire. The epitaxial layer 30 can be formed on the substrate 80 by metallic organic chemical vapor deposition (MOCVD). The epitaxial layer 30 forms as a p-n junction type semiconductor light-emitting structure, which may be gallium nitride-conductive based III-V group compound semiconductor. The epitaxial layer 30 includes an N-type layer 35 connected to the substrate 80, a light-emitting quantum-well layer 33 on the N-type layer 35, and a P-type layer 31 on the light-emitting quantum-well layer 33.

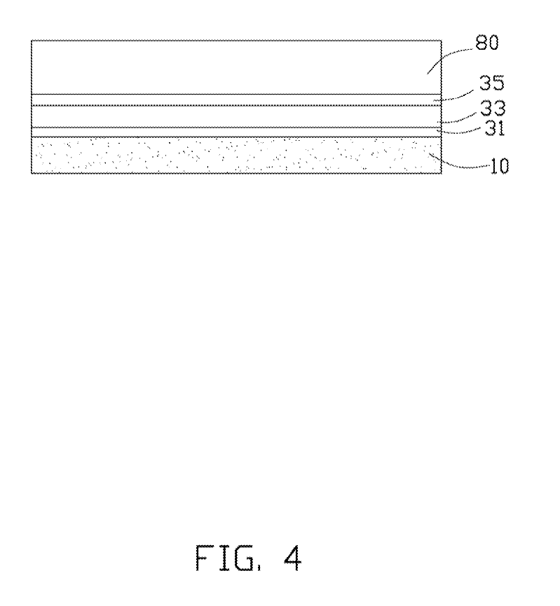

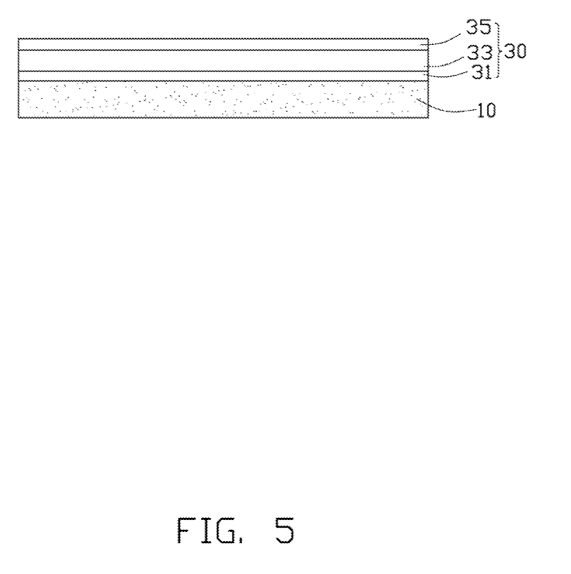

Referring to FIG. 4, an electrically conductive base 10 is then provided and coupled to the P-type layer 31 by electroplating. As shown in FIG. 5, the substrate 80 is then removed from the epitaxial layer 30 by laser lift-off, thereby exposing the N-type layer 35 of the epitaxial layer 30.

Referring to FIG. 6, the epitaxial layer 30 is then formed with a plurality of longitudinal grooves 36 and horizontal grooves 37 by inductively coupled plasma etching. The horizontal grooves 37 and the longitudinal grooves 36 extend through the epitaxial layer 30 to divide the epitaxial layer 30 into a plurality of separated LED dies 32 which are arranged as a matrix. Preferably, the LED die 32 has a width ranging from 100 μm to 5000 μm, and the grooves between the LED dies 32 has a width ranging from 1 μm to 10 μm.

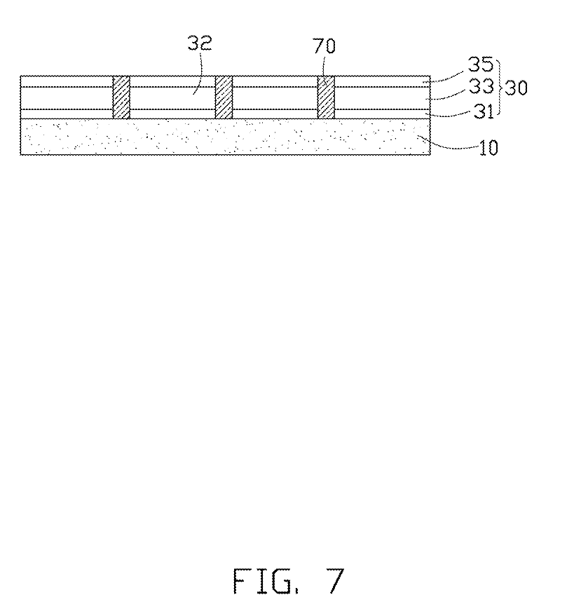

Referring to FIG. 7, transparent, electrically insulating material 70 is then filed in the horizontal grooves 37 and the longitudinal grooves 36 to insulate neighboring LED dies 32. The insulating material 70 has a height the same as a thickness of the epitaxial layer 30, such that a top of the insulating material 70 is coplanar with a top of the N-type layer 35.

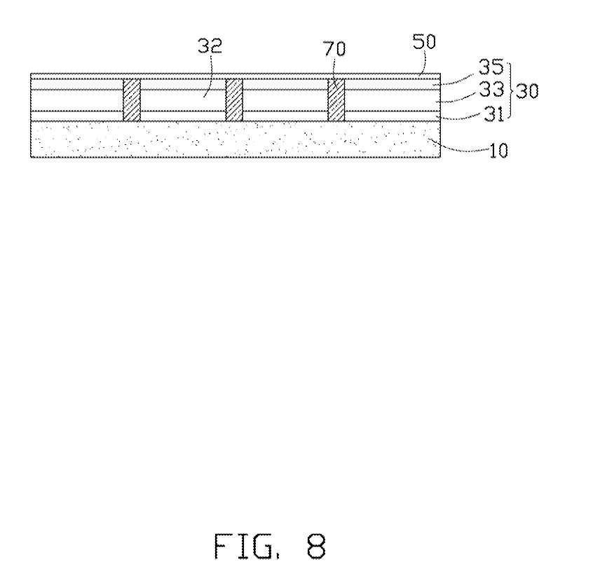

Referring to FIG. 8, a transparent, electrically-conducting layer 50 is then provided and coupled to the top of the N-type layer 35. The conducting layer 50 is indium tin oxide or Ni—Au mixture, which has an electrical resistance much less than that of the N-type layer 35. A thickness of the transparent, electrically-conducting layer 50 is about 0.01 μm to 0.2 μm. Finally, referring to FIG. 1 again, a metallic pad 90 is provided and fixed on a central portion of the transparent, electrically-conducting layer 50 by adhering or soldering to form the LED 100.

During operation, the pad 90 and the electrically conductive base 10 are connected to negative and positive poles of the power source, respectively, to cause the epitaxial layer 30 to emit light. When the electrons flow from the pad 90 towards the transparent, electrically-conducting layer 50, a majority of the electrons flow along the conducting layer 50 since the resistance of the conducting layer 50 is much less than that of the N-type layer 35, then the electrons flow downwards to the conductive base 10 via the LED dies 32 to cause the LED dies 32 to emit light. Since the electrons can be distributed over the entire conducting layer 50, crowding of the electrons is avoided, thereby improving a stability and a lifespan of the LED 100.

It is to be understood, however, that even though numerous characteristics and advantages of certain embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An LED, comprising:
an epitaxial layer comprising an N-type layer, a P-type layer and a light-emitting quantum-well layer between the N-type layer and P-type layer;
an electrically conductive base coupled to the P-type layer;
a transparent, electrically-conducting layer coupled to the N-type layer; and
a metallic pad disposed on the transparent, electrically-conducting layer.

2. The LED of claim 1, wherein an electrical resistance of the transparent, electrically-conducting layer is smaller than that of the N-type layer.

3. The LED of claim 2, wherein the transparent, electrically-conducting layer is indium tin oxide.

4. The LED of claim 2, wherein the transparent, electrically-conducting layer is Ni—Au mixture.

5. The LED of claim 2, wherein a thickness of the transparent, electrically-conducting layer ranges from 0.01 μm to 0.2 μm.

6. The LED of claim 1, wherein a plurality of grooves are defined in the epitaxial layer to divide the epitaxial layer into a plurality of separated LED dies, a width of the LED die ranging from 100 μm to 5000 μm, and a width of each of the grooves ranging from 1 μm to 10 μm.

7. The LED of claim 6, further comprising an electrically insulating material filled in the grooves to insulate neighboring LED dies.

8. The LED of claim 7, wherein a top of the electrically insulating material is coplanar with a top of the N-type layer of the epitaxial layer.

9. The LED of claim 7, wherein the electrically insulating material is silicon oxide.

10. The LED of claim 6, wherein the grooves comprise a plurality of parallel first grooves and a plurality of parallel second grooves intersecting the first grooves perpendicularly.

11. A method for manufacturing an LED, comprising steps of:
providing an LED wafer comprising a substrate and an epitaxial layer formed on the substrate;
coupling an electrically conductive base to the epitaxial layer;
removing the substrate from the epitaxial layer;
etching the epitaxial layer to form a plurality of grooves;
forming a transparent, electrically-conducting layer on the epitaxial layer; and
forming a metallic pad on the transparent, electrically-conducting layer.

12. The method of claim 11, further comprising filling an electrically insulating material in the grooves of the epitaxial layer before forming the transparent, electrically-conducting layer on the epitaxial layer.

13. The method of claim 11, wherein the grooves are formed by inductively coupled plasma etching.

14. The method of claim 11, wherein the metallic pad is fixed at a central portion of the transparent, electrically-conducting layer by adhering or soldering.

15. The method of claim 11, wherein the transparent, electrically-conducting layer is indium tin oxide or a Ni—Au mixture.

16. The method of claim 11, wherein the electrically conductive base is coupled to the P-type layer by electroplating.
